(19) United States
(12) Patent Application Publication
(10) Pub. No.: US 2026/0309148 A1
(43) Pub. Date: Oct. 8, 2026

(54) MONITORING SYSTEM AND MONITORING METHOD

(71) Applicant: FUJI CORPORATION, Chiryu (JP)

(72) Inventor: Satoshi IWASHIMA, Chiryu-shi (JP)

(73) Assignee: FUJI CORPORATION, Chiryu (JP)

(21) Appl. No.: 19/483,356

(22) PCT Filed: Jun. 28, 2023
(86) PCT No.: PCT/JP2023/023965

§ 371 Date: Nov. 11, 2025

(51) Int. Cl. F04B 51/00; F04B 41/06; H05K 13/04

(52) U.S. Cl. CPC F04B 51/00; F04B 41/06; H05K 13/0409

(57) ABSTRACT

A monitoring system for monitoring pressures of multiple vacuum pumps provided in a working device includes: a sensor that detects a pressure of an air flow path communicating with the multiple vacuum pumps; a pressure acquisition section that executes acquisition processing of acquiring a detection value of the sensor as a pressure of an operating vacuum pump in a state in which one of the multiple vacuum pumps is operated and the remaining vacuums pump are stopped, while sequentially switching the vacuum pump to be operated; and a determination section that determines a state of each of the multiple vacuum pumps based on the pressure acquired in the acquisition processing.

### TECHNICAL FIELD

The present description discloses a monitoring system and a monitoring method.

### BACKGROUND ART

Conventionally, proposals have been made for monitoring a vacuum pressure generated by a vacuum pump or the like. For example, Patent Literature 1 describes that time-series data of a vacuum pressure detected by a detection sensor is stored, presence or absence of an abnormality in a pipe that supplies the vacuum pressure is determined by obtaining a change amount of the time-series data, and maintenance such as cleaning is performed.

### CITATION LIST

### Patent Literature

Patent Literature 1: JP-A-H05-185390

### BRIEF SUMMARY

### Technical Problem

As mentioned above, monitoring the vacuum pressure to ensure that a proper vacuum pressure is supplied is an important issue in achieving stabilization of production work and the like, and further improvement is required.

A main object of the present disclosure is to more appropriately perform monitoring of a vacuum pump.

### Solution to Problem

The present disclosure employs the following means in order to achieve the above-mentioned main object.

The monitoring system of the present disclosure is
a monitoring system for monitoring pressures of multiple vacuum pumps provided in a working device, the monitoring system including:
a sensor configured to detect a pressure of an air flow path communicating with the multiple vacuum pumps;
a pressure acquisition section configured to execute acquisition processing of acquiring a detection value of the sensor as a pressure of an operating vacuum pump in a state in which one of the multiple vacuum pumps is operated and the remaining vacuum pumps are stopped, while sequentially switching the vacuum pump to be operated; and
a determination section configured to determine a state of each of the multiple vacuum pumps based on the pressure acquired in the acquisition processing.

In the mounting device of the present disclosure, since a pressure of a vacuum pump is acquired and a state is determined, monitoring of the vacuum pump can be more appropriately performed.

### BRIEF DESCRIPTION OF DRAWINGS

FIG. 1 is a configuration diagram showing a schematic configuration of mounting system 1 including mounting device 10.

FIG. 2 is a top view of mounting device 10.

FIG. 3 is a configuration diagram showing a schematic configuration of pressure supply device 70.

FIG. 4 is a flowchart showing an example of pressure-related information transmission processing.

FIG. 5 is a flowchart showing an example of pressure acquisition processing.

FIG. 6 is a diagram illustrating an example of a pump state display screen.

FIG. 7 is a diagram illustrating an example of the pump state display screen.

FIG. 8 is a diagram illustrating an example of the pump state display screen.

FIG. 9 is a flowchart showing an example of pump state confirmation processing.

FIG. 10 is a diagram illustrating an example of pressure-related information database 103a.

FIG. 11 is a diagram illustrating an example of a manner of determining a pump state.

FIG. 12 is a configuration diagram showing a schematic configuration of pressure supply device 170 of an alternative embodiment.

### Description of Embodiments

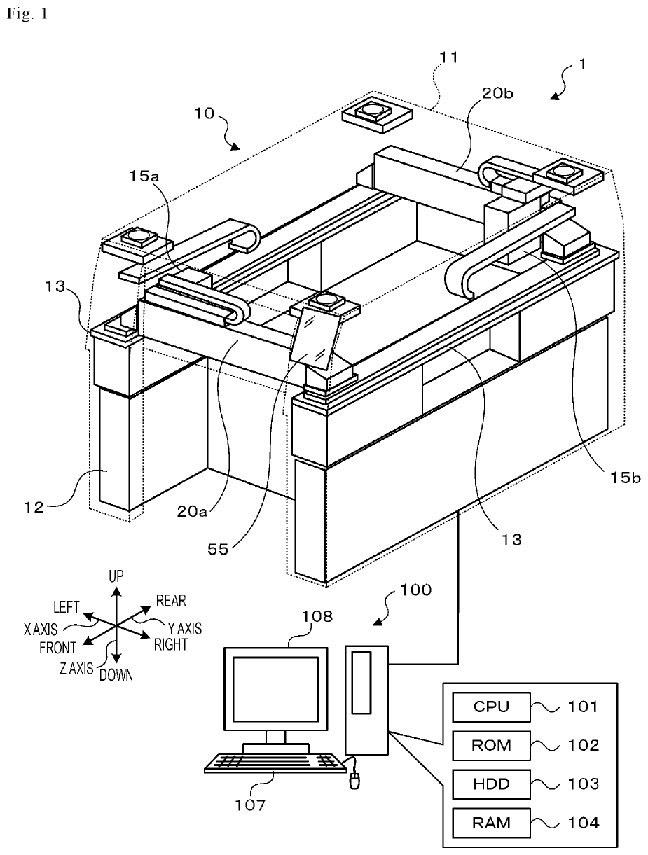

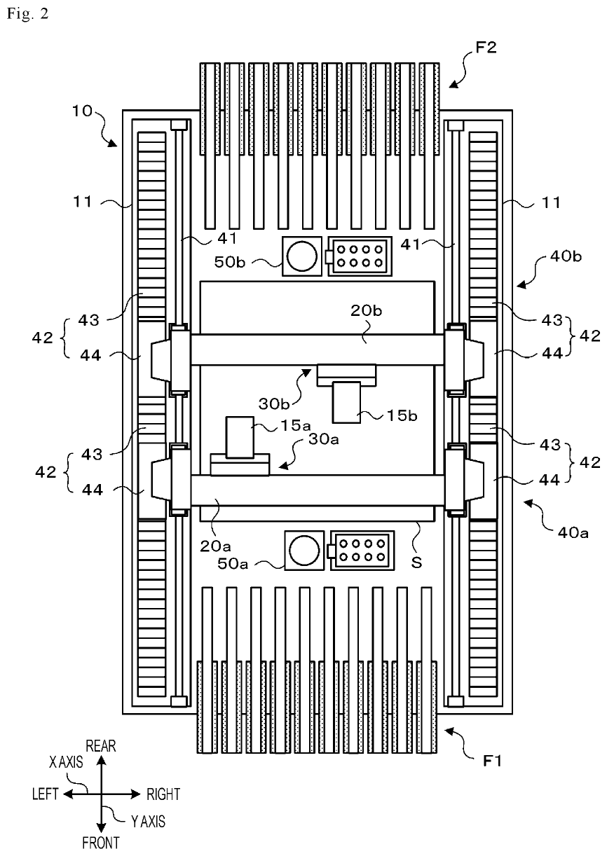

An embodiment of the present disclosure will be described with reference to the drawings. FIG. 1 is a configuration diagram showing a schematic configuration of mounting system 1 including mounting device 10. FIG. 2 is a top view of mounting device 10. Mounting system 1 includes mounting device 10 and management device 100 that manages mounting device 10. Mounting system 1 includes a mounting line in which mounting devices 10 that perform a mounting process of picking up components supplied from a feeder and mounting the components on board S are disposed side by side along a conveyance direction (X-axis direction) of board S. FIG. 1 shows only one mounting device 10. In addition, mounting system 1 may include, in the mounting line, a solder printing device, an inspection device, a reflow oven, and the like. It should be noted that, in the present embodiment, a left-right direction in FIG. 1 is an X-axis direction, a front-rear direction is a Y-axis direction, and an up-down direction is a Z-axis direction.

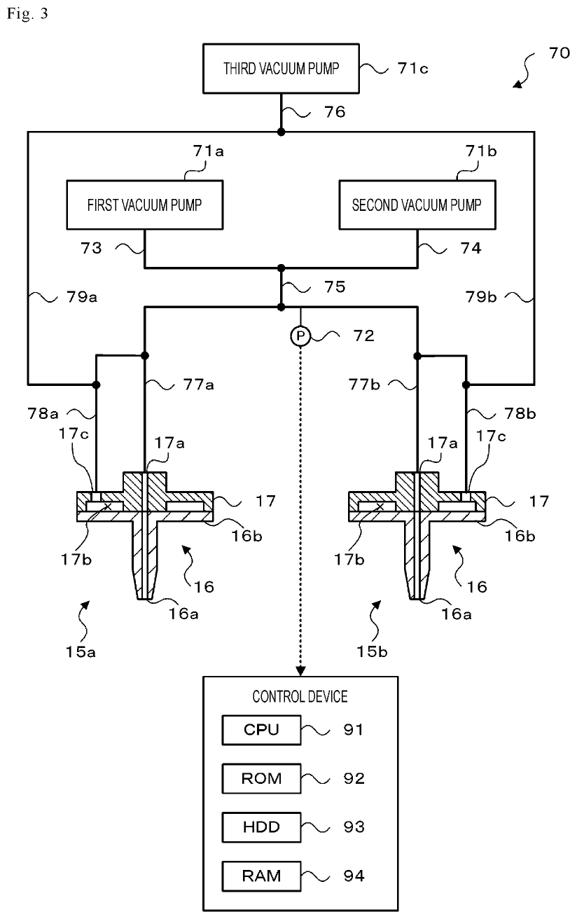

Mounting device 10 includes a board conveyance device (not shown), first and second feeder sections F1 and F2, first and second heads 15a and 15b, first and second slide members 20a and 20b, first and second X-axis moving devices 30a and 30b, first and second Y-axis moving devices 40a and 40b, and first and second part cameras 50a and 50b. These are mounted on base 12 and housed in housing 11. Additionally, mounting device 10 includes display operation panel 55 provided in housing 11, pressure supply device 70 (refer to FIG. 3), and control device 90 (refer to FIG. 3). Support stands 13 extending in the front-rear direction are provided on both left and right sides in an upper stage of base 12. First head 15a and second head 15b may be simply referred to as head 15. First part camera 50a and second part camera 50b may be simply referred to as part camera 50. The board conveyance device conveys board S on a conveyor belt from left to right by driving the conveyor belt with a motor.

First and second feeder sections F1 and F2 are provided on both front and rear sides of base 12, and feeders that supply components are attached to and detached from the feeder sections. First feeder section F1 supplies a component to first head 15a, and second feeder section F2 supplies a component to second head 15b. The feeder section may be provided on only one side of the front and rear sides.

Each of first and second heads 15a and 15b includes nozzle 16 (refer to FIG. 3) that picks up a component by suction, and nozzle holding section 17 (refer to FIG. 3) that holds nozzle 16 and that is liftable and lowerable. First head 15a is supported by first slide member 20a to be movable in the left-right (X-axis) direction. Second head 15b is supported by second slide member 20b to be movable in the left-right (X-axis) direction.

First and second slide members 20a and 20b are elongated members extending in the left-right (X-axis) direction, are disposed in parallel with each other, are supported across pair of left and right Y-axis linear guides 41 (guide rails) made of iron that are shared with each other, and move in the front-rear (Y-axis) direction along pair of Y-axis linear guides 41.

First Y-axis moving device 40a moves first slide member 20a in the front-rear (Y-axis) direction. Second Y-axis moving device 40b moves second slide member 20b in the front-rear (Y-axis) direction. First and second Y-axis moving devices 40a and 40b include pair of left and right Y-axis linear guides 41 and Y-axis linear motors 42 respectively provided on the left and right sides. Y-axis linear motor 42 is configured as a flat-type linear motor including Y-axis stator 43 that is fixed to support stand 13 to extend in the front-rear direction, and Y-axis mover 44 that faces Y-axis stator 43 with a predetermined spacing in the up-down direction and that is fixed to first slide member 20a or second slide member 20b. Y-axis stator 43 includes multiple permanent magnets that are flatly disposed along Y-axis linear guide 41 such that polarities of N poles and S poles alternately differ. Y-axis mover 44 includes multiple cores each formed by stacking electromagnetic steel sheets, and phase coils each wound around a corresponding core. Y-axis mover 44 moves in the front-rear (Y-axis) direction by applying three-phase alternating currents to each phase coil.

In addition, although not shown, a pair of upper and lower X-axis linear guides (guide rails) made of iron, which extend in parallel with each other in the left-right direction, are joined on side surfaces (side walls) of respective frames of first and second slide members 20a and 20b that face each other. First and second heads 15a and 15b are supported by first and second slide members 20a and 20b to be movable in the left-right direction along the X-axis linear guides. First X-axis moving device 30a moves first head 15a in the left-right (X-axis) direction. Second X-axis moving device 30b moves second head 15b in the left-right (X-axis) direction. First and second X-axis moving devices 30a and 30b include, although not shown, X-axis linear guides and X-axis linear motors configured as flat-type linear motors, similarly to first and second Y-axis moving devices 40a and 40b.

As described above, mounting device 10 moves slide member 20 (20a, 20b) in the front-rear (Y-axis) direction using Y-axis moving device 40 (40a, 40b), and moves head 15 (15a, 15b) in the left-right (X-axis) direction with respect to slide member 20 using X-axis moving device 30 (30a, 30b). As a result, head 15 (15a, 15b) can move in the front-rear and left-right directions (XY-axis directions).

First and second part cameras 50a and 50b are provided between first and second feeder sections F1 and F2 and the board conveyance device, respectively. First and second part cameras 50a and 50b have imaging ranges above the part cameras, and generate captured images by capturing target objects such as components picked up by suction of nozzle 16, from below. Display operation panel 55 is configured as a touch panel that displays various information and that receives an input operation from a worker.

As shown in FIG. 3, control device 90 includes CPU 91, ROM 92, HDD 93, and RAM 94. Control device 90 causes mounting device 10 to perform the mounting process based on a production job of board S. The production job defines which components are to be mounted on board S in which order in mounting device 10, how many boards S with components mounted thereon are to be produced, and the like. Control device 90 inputs captured images of first and second part cameras 50a and 50b, detection values of pressure sensor 72 of pressure supply device 70, operation signals based on the input operation to display operation panel 55, and the like. Control device 90 outputs drive signals to each feeder, the board conveyance device, first and second heads 15a and 15b, first and second X-axis moving devices 30a and 30b, first and second Y-axis moving devices 40a and 40b, and the like, drive signals to each vacuum pump 71 of pressure supply device 70 and solenoid valves (not shown), display signals to display operation panel 55, and the like.

Management device 100 manages the production and state of one or more mounting devices 10, and includes CPU 101, ROM 102, HDD 103, and RAM 104. HDD 103 stores a production plan database including production jobs, pressure-related information database 103a, which will be described below, and the like. Additionally, management device 100 includes input device 107 such as a mouse and a keyboard, and display 108. Management device 100 transmits a production job to control device 90 and acquires information regarding a production status and an operation state of mounting device 10 from control device 90.

FIG. 3 is a configuration diagram showing a schematic configuration for supplying a negative pressure in pressure supply device 70. Pressure supply device 70 includes, as negative pressure sources, three vacuum pumps 71, that is, first vacuum pump 71a, second vacuum pump 71b, and third vacuum pump 71c. As shown in FIG. 3, nozzle 16 picks up a component by suction at suction port 16a at a tip (lower end) of a tubular shaft potion, and flange portion 16b is formed at an upper end of the shaft portion. Nozzle holding section 17 is formed with center hole 17a that vertically penetrates through a central portion, annular recessed portion 17b provided in a lower surface (holding surface), and communication hole 17c that vertically penetrates to communicate from an upper surface to a bottom surface of recessed portion 17b. Recessed portion 17b of nozzle holding section 17 is covered with an upper surface of flange portion 16b of nozzle 16, thereby forming a negative pressure chamber. Negative pressure is supplied to the negative pressure chamber (into recessed portion 17b) through communication hole 17c, thereby enabling nozzle holding section 17 to pick up and hold nozzle 16 by suction. Additionally, negative pressure is supplied to suction port 16a through center hole 17a of nozzle holding section 17 and the center hole of the shaft portion, thereby enabling nozzle 16 to pick up and hold a component at suction port 16a by suction. Mounting device 10 includes two heads 15 (15a, 15b) and needs to supply negative pressure required for respective nozzles 16 and nozzle holding sections 17. That is, since it is necessary to generate a relatively large negative pressure, multiple vacuum pumps 71 (for example, three) are provided. In addition, although not shown, a permanent magnet is embedded in a part of the bottom surface of recessed portion 17b. Further, a metal plate is embedded at a position of the upper surface (a held surface) of flange portion 16b of nozzle 16 that faces the permanent magnet of recessed portion 17b. Therefore, nozzle 16 is held by nozzle holding section 17 by a suction force of the negative pressure and an attraction force of the magnet.

Pressure supply device 70 includes, as air flow paths capable of supplying a negative pressure, first flow path 73 connected to first vacuum pump 71a, second flow path 74 connected to second vacuum pump 71b, connection flow paths 75, 79a, and 79b, third flow path 76 connected to third vacuum pump 71c, component suction pickup flow paths 77a and 77b, and nozzle holding flow paths 78a and 78b. Connection flow path 75 is connected to first flow path 73 and second flow path 74 and is also connected to component suction pickup flow paths 77a and 77b. Component suction pickup flow path 77a is connected to center hole 17a of nozzle holding section 17 of head 15a, and supplies negative pressure for picking up a component by suction to suction port 16a of nozzle 16 of head 15a through center hole 17a. Component suction pickup flow path 77b is connected to center hole 17a of nozzle holding section 17 of head 15b, and supplies a negative pressure for picking up a component by suction to suction port 16a of nozzle 16 of head 15b through center hole 17a. Nozzle holding flow path 78a is connected to component suction pickup flow path 77a and is also connected to communication hole 17c of nozzle holding section 17 of head 15a, and supplies negative pressure for holding (picking up by suction) nozzle 16 into recessed portion 17b through communication hole 17c. Nozzle holding flow path 78b is connected to component suction pickup flow path 77b and is also connected to communication hole 17c of nozzle holding section 17 of head 15b, and supplies negative pressure for holding (picking up by suction) nozzle 16 into recessed portion 17b through communication hole 17c. Connection flow path 79a is connected to third flow path 76 and nozzle holding flow path 78a. Connection flow path 79b is connected to third flow path 76 and nozzle holding flow path 78b.

Additionally, pressure supply device 70 includes pressure sensor 72 that detects a pressure (negative pressure). Pressure sensor 72 is attached to, for example, component suction pickup flow path 77b. Although not shown, pressure supply device 70 is configured to supply positive pressure to the negative pressure chamber of nozzle holding section 17 and suction port 16a of nozzle 16. As a result, it is possible to release suction pickup of nozzle 16 picked up by suction of nozzle holding section 17, and to release suction pickup of a component picked up by suction of nozzle 16 and mount the component on board S.

Mounting device 10 configured in this manner performs the mounting process of picking up a component and mounting the component on board S as follows. In the mounting process, CPU 91 moves head 15 (15a, 15b) to a position above a component supply position of the feeder, and lowers nozzle 16 to pick up the component by suction. When the suction pickup of the component is completed, CPU 91 moves head 15 to a position above part camera 50 (50a, 50b) and captures an image of the component picked up by suction of nozzle 16. CPU 91 determines misalignment in suction pickup of the component with respect to nozzle 16 based on the captured image, and corrects a target mounting position to eliminate the misalignment in suction pickup. Then, CPU 91 moves head 15 to a position above board S based on the target mounting position, lowers nozzle 16, and mounts the component on board S. CPU 91 repeatedly performs such suction pickup of the component and mounting of the component for all components that are mounting targets.

In addition, during the mounting process, CPU 91 collects various information, and stores the various information in HDD 93 or transmits the various information to management device 100. As one example of the various information, a pickup success rate and a mounting success rate are collected. The pickup success rate is calculated by dividing the number of components that have been successfully picked up by suction of nozzle 16 without pickup failure by the number of all the components that are mounting targets. The pickup failure occurs with a component that has dropped from nozzle 16, and a component whose amount of misalignment in suction pickup determined based on the image captured by part camera 50 is outside a predetermined allowable range, and the like. Further, the mounting success rate is calculated by dividing the number of components that have been successfully mounted on board S without mounting failure by the number of all the components that are mounting targets. The mounting failure occurs with a component that has been carried back without being normally released from suction pickup when mounted on board S, and the like. Additionally, the pickup success rate and the mounting success rate need only be calculated, for example, as success rates from the start of production to the end of production in a predetermined period (for example, one day or the like). The pickup failure and the mounting failure are affected by positional misalignment of supplied components, defective shapes of components, warpage of board S, and the like; however, the pickup failure and the mounting failure are also affected by pressure failure of each vacuum pump 71 of pressure supply device 70.

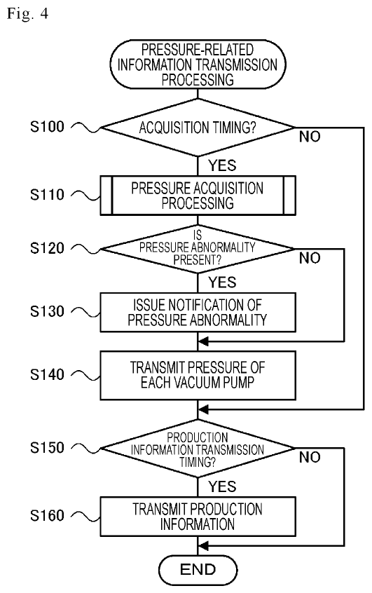

In addition, in mounting system 1, various processes for confirming the state of each vacuum pump 71 and necessity of maintenance are performed. FIG. 4 is a flowchart showing an example of pressure-related information transmission processing, which is executed by CPU 91 of control device 90.

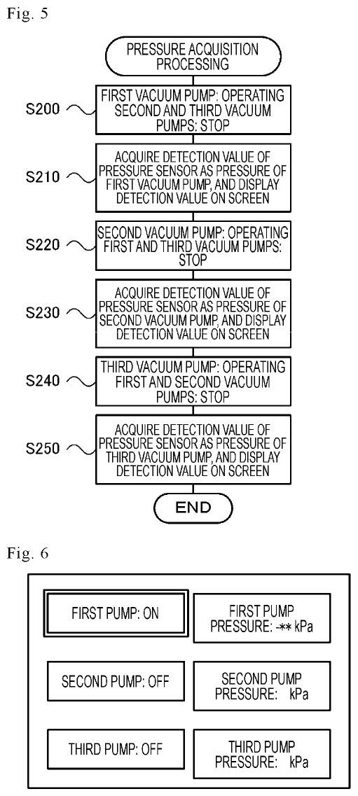

In the pressure-related information transmission processing, CPU 91 determines whether a pressure acquisition timing of each vacuum pump 71 has been reached (S100); when it is determined that the acquisition timing has been reached, CPU 91 executes pressure acquisition processing of FIG. 5 (S110); and when it is determined that the acquisition timing has not been reached, CPU 91 proceeds to S150. The pressure acquisition timing needs only to be, for example, a timing before mounting device 10 starts the mounting process, a timing when an instruction to confirm a pressure is issued from the worker via display operation panel 55 in a state in which production is not performed, or the like.

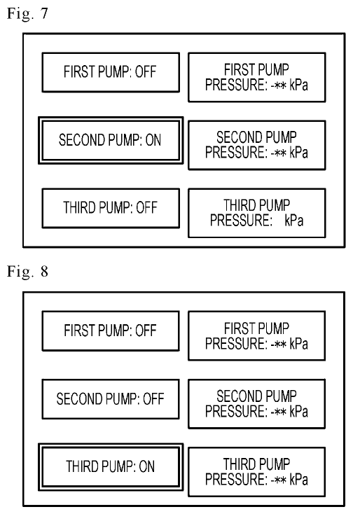

In the pressure acquisition processing of FIG. 5 (S110), CPU 91 first sets a state (first state) in which first vacuum pump 71a is operated (turned on) and second vacuum pump 71b and third vacuum pump 71c are stopped (turned off) (S200). Then, CPU 91 acquires the detection value of pressure sensor 72 as the pressure of operating first vacuum pump 71a and displays the detection value on display operation panel 55 (S210, FIG. 6). In a pump state display screen, for example, as shown in FIG. 6, first pump (first vacuum pump 71a) being turned on and the pressure (-** kPa) are displayed. Next, CPU 91 sets a state (second state) in which second vacuum pump 71b is operated and first vacuum pump 71a and third vacuum pump 71c are stopped (S220). Then, CPU 91 acquires the detection value of pressure sensor 72 as the pressure of operating second vacuum pump 71b and displays the detection value on display operation panel 55 (S230, FIG. 7).

Subsequently, CPU 91 sets a state (third state) in which third vacuum pump 71c is operated and first vacuum pump 71a and second vacuum pump 71b are stopped (S240). Then, CPU 91 acquires the detection value of pressure sensor 72 as the pressure of operating third vacuum pump 71c, displays the detection value on display operation panel 55 (S250, FIG. 8), and ends the pressure acquisition processing. As described above, in the pressure acquisition processing, the detection values of pressure sensor 72 are sequentially acquired as the pressures of operating vacuum pumps 71 while sequentially switching the states in which one of vacuum pumps 71 is operated (turned on) and remaining two are stopped (turned off).

When the pressure acquisition processing is executed in this manner, CPU 91 determines whether there is a pressure abnormality in any of vacuum pumps 71 (S120). CPU 91 determines that there is a pressure abnormality when any of the pressures acquired in S210, S230, and S250 of FIG. 5 is on a positive side (an absolute value is small) relative to predetermined pressure threshold value Pl for abnormality determination. CPU 91 issues a notification of the pressure abnormality when CPU 91 determines that there is a pressure abnormality (S130), and skips S130 when CPU 91 determines that there is no pressure abnormality. In S130, CPU 91 may issue a notification by, for example, displaying information indicating the pressure abnormality on display operation panel 55, or may issue a notification by turning on a warning lamp (not shown), outputting a warning sound from a speaker, or the like. By the notification of the pressure abnormality, prompt action by the worker such as exchanging vacuum pump 71 determined to be abnormal becomes possible. In addition, CPU 91 transmits the pressure of each vacuum pump 71 acquired (detected) in the pressure acquisition processing to management device 100 (S140). CPU 91 may transmit information indicating the pressure abnormality to management device 100, and management device 100 may display the information indicating the pressure abnormality on display 108.

Next, CPU 91 determines whether a transmission timing of production information including the pickup success rate, the mounting success rate, and the like mentioned above has been reached (S150). The transmission timing is a timing at which production (mounting process) in a predetermined period (for example, one day) ends, or the like. CPU 91 transmits the production information to management device 100 (S160) and ends the pressure-related information transmission processing when CPU 91 determines that the transmission timing has been reached, and skips S160 and ends the pressure-related information transmission processing when CPU 91 determines that the transmission timing has not been reached.

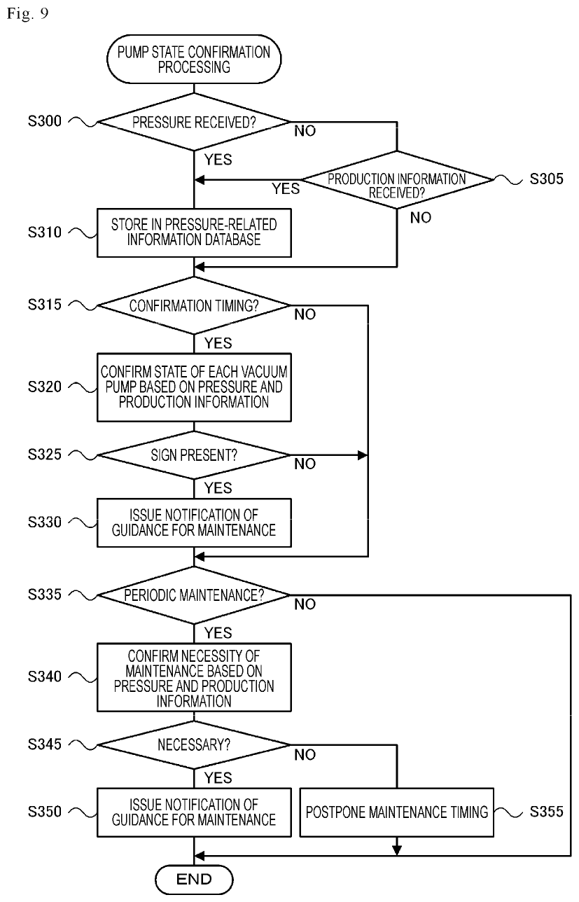

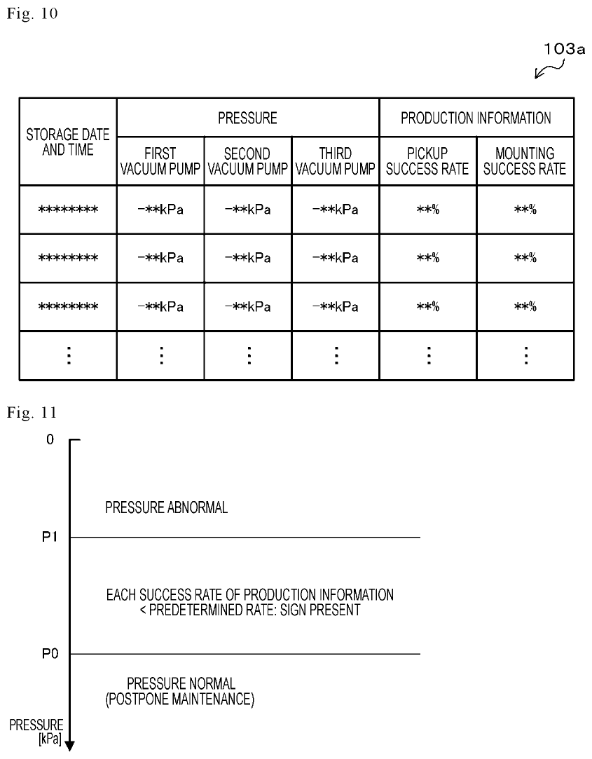

Next, processing of management device 100 will be described. FIG. 9 is a flowchart showing an example of pump state confirmation processing, which is executed by CPU 101 of management device 100. CPU 101 determines whether the pressure transmitted from mounting device 10 has been received (S300) and whether the production information transmitted from mounting device 10 has been received (S305). When CPU 101 determines that the pressure has been received or the production information has been received, CPU 101 stores the pressure or the production information in pressure-related information database 103a (S310, FIG. 10).

When the pressure has been received, CPU 101 stores the pressure in association with latest production information not associated with the pressure in a case where the latest production information is present in pressure-related information database 103a, and updates a storage date and time. Additionally, in a case where no production information not associated with the pressure is present in pressure-related information database 103a, CPU 101 stores the pressure without associating the pressure with the production information. When the production information has been received, CPU 101 stores the production information in association with a latest pressure not associated with the production information in a case where the latest pressure is present in pressure-related information database 103a, and updates a storage date and time. Further, in a case where no pressure not associated with the production information is present in pressure-related information database 103a, CPU 101 stores the production information without associating the production information with the pressure. Therefore, in pressure-related information database 103a, the pressure and the production information having close reception dates and times (acquisition dates and times) are associated with each other and stored in chronological order.

Next, CPU 101 determines whether a confirmation timing for confirming the state of each vacuum pump 71 has been reached (S315). When the pressure and the production information have been stored in association with each other in S310, CPU 101 determines in S315 that the confirmation timing has been reached. Alternatively, the timing may be a timing at which an instruction to confirm the state is issued from the worker via input device 107, or the like. When CPU 101 determines that the confirmation timing has been reached, CPU 101 confirms the state of each vacuum pump 71 based on the pressure and the production information stored in pressure-related information database 103a (S320), and determines whether there is a sign of abnormality (S325). When CPU 101 determines a sign state indicating that there is a sign of abnormality in any of vacuum pumps 71, CPU 101 issues a notification of guidance for maintenance of vacuum pump 71 (S330), and skips S330 when CPU 101 determines that there is no sign.

Here, FIG. 11 is a diagram illustrating an example of a manner of determining the pump state, with the pressure represented on a vertical axis. As mentioned above, when the pressure of vacuum pump 71 is on the positive side (the absolute value is small) relative to predetermined pressure threshold value P1 for abnormality determination and is within a predetermined abnormal range, the pressure is determined to be abnormal. In the pump state confirmation processing performed by management device 100, the pressure may be compared with pressure threshold value P1 to determine a pressure abnormality. In addition, when the pressure of vacuum pump 71 is on a negative side (the absolute value is large) relative to pressure threshold value PO and is within a predetermined normal range, the pressure is determined to be normal. Further, CPU 101 determines that there is a sign of abnormality when the pressure of vacuum pump 71 is between pressure threshold value P0 and pressure threshold value Pl and the pickup success rate and the mounting success rate of the production information are each less than a predetermined rate. The predetermined rate for the pickup success rate and the predetermined rate for the mounting success rate may be different values. Additionally, when a first success rate of the pickup success rate and the mounting success rate is less than the predetermined rate, CPU 101 may determine that there is a sign of abnormality even when a second success rate is equal to or greater than the predetermined rate. As described above, even when the pressure of vacuum pump 71 is not within the abnormal range, it is possible to obtain a tendency of pressure drop based on the pickup success rate and the mounting success rate, determine that there is a sign of abnormality, and issue a notification of guidance for maintenance. Further, since the pressure and the production information are stored in pressure-related information database 103a in chronological order, CPU 101 may determine a sign of abnormality based on a trend of change in pressure over time and a tendency of change in production information. For example, CPU 101 may determine that there is a sign of abnormality when CPU 101 obtains a trend such that a change amount of the pressure to the positive side is equal to or greater than a predetermined pressure, when CPU 101 obtains a trend such that a change amount of the pickup success rate or the mounting success rate is equal to or greater than a predetermined rate, or the like.

Subsequently, CPU 101 determines whether a timing of periodic maintenance of any of vacuum pumps 71 has been reached (S335), and when CPU 101 determines that the timing of periodic maintenance has not been reached, CPU 101 ends the pump state confirmation processing. The timing of periodic maintenance is a timing determined in advance based on an elapsed period from the previous maintenance. On the other hand, when CPU 101 determines that the timing of periodic maintenance of any of vacuum pumps 71 has been reached, CPU 101 confirms the necessity of maintenance based on the pressure of vacuum pump 71 and the production information (S340), and determines whether periodic maintenance is necessary (S345).

Here, CPU 101 needs only to determine that periodic maintenance is necessary, for example, when the pressure of vacuum pump 71 is on the positive side relative to pressure threshold value PO (refer to FIG. 11). In addition, CPU 101 needs only to determine that periodic maintenance is unnecessary when the pressure of vacuum pump 71 is within the normal range because the pressure is on the negative side relative to pressure threshold value PO. CPU 101 may determine that maintenance is unnecessary when the pressure of vacuum pump 71 is within the normal range and the pickup success rate and the mounting success rate of the production information are each equal to or greater than a predetermined rate.

When CPU 101 determines in S345 that periodic maintenance is necessary, CPU 101 issues a notification of guidance for maintenance (S350) and ends the pump state confirmation processing. On the other hand, when CPU 101 determines that periodic maintenance is not necessary, CPU 101 postpones the timing of periodic maintenance of vacuum pump 71 (S355) and ends the pump state confirmation processing. CPU 101 needs only to postpone the timing by deferring the timing for a certain period such as a predetermined number of days.

Here, correspondence relationships between the elements of the present embodiment and the elements of the present disclosure will be clarified. Pressure sensor 72 of the present embodiment corresponds to a sensor of the present disclosure, control device 90 that executes S110 (pressure acquisition processing) of the pressure-related information transmission processing corresponds to a pressure acquisition section, and control device 90 that executes S120 and S130 of the pressure-related information transmission processing and management device 100 that executes the pump state confirmation processing correspond to a determination section. Control device 90 that executes S160 of the pressure-related information transmission processing corresponds to an information acquisition section, and management device 100 (HDD 103) that stores pressure-related information database 103a corresponds to a storage section. In the present embodiment, an example of the monitoring method of the present disclosure is also clarified by describing an operation of mounting system 1.

In mounting system 1 of the embodiment described above, the pressure acquisition processing of acquiring the detection value of pressure sensor 72 as the pressure of operating vacuum pump 71 in a state in which one of multiple vacuum pumps 71 is operated and the remaining vacuum pumps are stopped, while sequentially switching vacuum pump 71 to be operated, is executed. Then, the state of each of multiple vacuum pumps 71 is determined based on the acquired pressure, so that monitoring of vacuum pump 71 can be more appropriately performed. Additionally, the states of multiple vacuum pumps 71 can be determined with the detection value of one pressure sensor 72, and it is not necessary to provide the same number of pressure sensors 72 as vacuum pumps 71, so that it is possible to achieve downsizing of pressure supply device 70 while reducing cost.

Further, since the pressure acquisition processing is executed at a timing before the mounting process (production work) of mounting device 10 is started, it is possible to prevent the production work from being hindered by an abnormality of vacuum pump 71.

In addition, the production information affected by the pressure change of vacuum pump 71 in the mounting process is acquired, and the pressure acquired in the pressure acquisition processing and the production information acquired in the production work after the execution of the pressure acquisition processing are stored in pressure-related information database 103a in association with each other. Then, the state of each of multiple vacuum pumps 71 is determined based on the pressure in pressure-related information database 103a and the production information associated with the pressure. Therefore, it is possible to more appropriately perform monitoring of vacuum pump 71 based on the pressure and the production information.

Further, when the pressure is within the abnormal range, it is determined that vacuum pump 71 is in a state of pressure abnormality, and when the pressure is not within the abnormal range, it is determined whether vacuum pump 71 is in a state requiring maintenance (sign state) based on the production information associated with the pressure. Therefore, it is possible to appropriately determine a sign of abnormality of vacuum pump 71 and to cause an action such as maintenance to be performed at an early stage.

Additionally, even when vacuum pump 71 has reached the timing of periodic maintenance, the timing of periodic maintenance is postponed in a case where the pressure is within the predetermined normal range. Therefore, it is possible to appropriately determine the necessity of periodic maintenance, and to postpone the periodic maintenance and continue the mounting process when the periodic maintenance is not immediately necessary. Therefore, it is possible to prevent frequent periodic maintenance, thereby reducing the worker's workload and enabling the mounting process to be performed efficiently.

It should be noted that the present disclosure is not limited to the embodiment mentioned above, and it goes without saying that the present disclosure can be implemented in various aspects as long as the aspects belong to a technical scope of the present disclosure.

For example, in the embodiment mentioned above, the timing of periodic maintenance is postponed as long as the pressure is within the predetermined normal range even when the timing of periodic maintenance has been reached; however, the configuration is not limited to this, and maintenance may be performed regardless of the pressure when the timing of periodic maintenance has been reached. That is, processes of S340, S345, and S355 of the pump state confirmation processing may be omitted.

In the embodiment, when the pressure is not within the abnormal range, it is determined whether vacuum pump 71 is in a state requiring maintenance based on the production information associated with the pressure; however, the configuration is not limited to this, and such a determination may be omitted. For example, when the pressure is not within the abnormal range and is between the normal range and the abnormal range (between pressure threshold value P0 and pressure threshold value P1 in FIG. 11), it may be determined to be a state requiring maintenance regardless of the production information.

In the embodiment, the timing before the start of the mounting process has been described as an example of the pressure acquisition timing; however, the configuration is not limited to this, and the timing after the end of the mounting process, or the like may be employed. That is, the production information acquired in the production work and the pressure acquired in the pressure acquisition processing after the end of the production work may be stored in association with each other. Further, the configuration is not limited to storing in chronological order in pressure-related information database 103a, and the pressure and the production information need only be stored in association with each other and determination of a sign of abnormality and the like need only be performed. Alternatively, the configuration is not limited to acquiring the production information, and various determinations such as the state of vacuum pump 71 and the timing of periodic maintenance may be performed based on the pressure acquired in pressure acquisition processing.

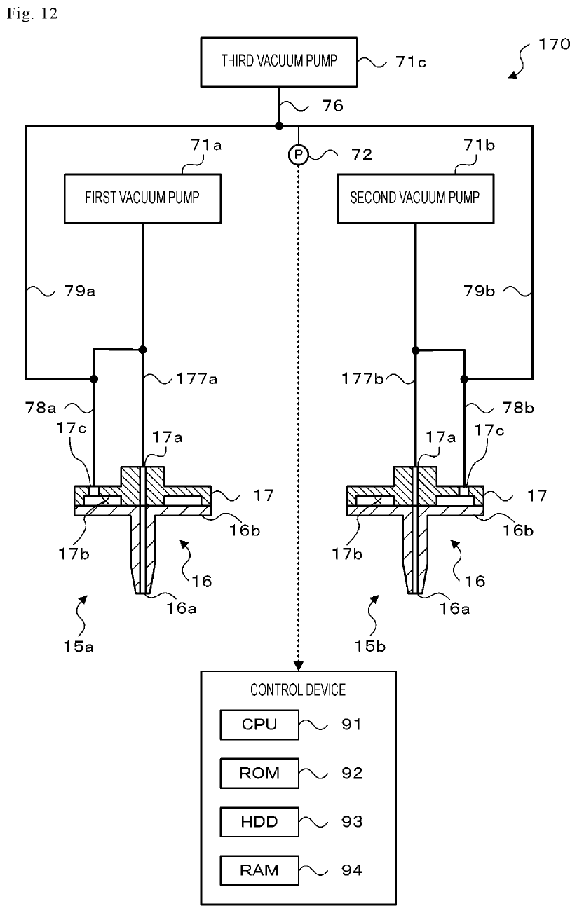

In addition, pressure supply device 70 may be configured as in the following alternative embodiment. FIG. 12 is a configuration diagram showing a schematic configuration of pressure supply device 170 of the alternative embodiment. In pressure supply device 170 of the alternative embodiment, first flow path 73, second flow path 74, and connection flow path 75 of the embodiment are omitted. Additionally, in the alternative embodiment, component suction pickup flow path 177a is connected to first vacuum pump 71a and is also connected to center hole 17a of nozzle holding section 17 of head 15a, and component suction pickup flow path 177b is connected to second vacuum pump 71b and is also connected to center hole 17a of nozzle holding section 17 of head 15b. Other than these, third flow path 76, nozzle holding flow paths 78a and 78b, and connection flow paths 79a and 79b are connected in the same manner as in the embodiment. Further, pressure sensor 72 of the alternative embodiment is attached to, for example, connection flow path 79b.

That is, pressure supply device 170 of the alternative embodiment is different from pressure supply device 70 of the embodiment in that flow paths (first flow path 73, second flow path 74, and connection flow path 75) for connecting both first vacuum pump 71a and second vacuum pump 71b to each other and directly supplying negative pressures to nozzle holding section 17 of heads 15a and 15b are not provided. In this alternative embodiment as well, in the same manner as in the embodiment, by executing the pressure acquisition processing of acquiring the detection value of pressure sensor 72 as the pressure of operating vacuum pump 71 in a state in which one of multiple vacuum pumps 71 is operated and the remaining vacuum pumps are stopped, monitoring of multiple vacuum pumps 71 can be more appropriately performed.

In the embodiment, an example has been described in which pressure supply device 70 includes three vacuum pumps 71; however, the configuration is not limited to this, and two or more vacuum pumps 71 need only be provided. Alternatively, the configuration is not limited to multiple vacuum pumps 71, and only one vacuum pump 71 may be provided. Then, in a state in which vacuum pump 71 is operated, the detection value of pressure sensor 72 needs only to be acquired as the pressure of operating vacuum pump 71, and the state of vacuum pump 71 or the like needs only to be determined in the same manner as in the embodiment. In addition, mounting device 10 includes two heads 15, but may include single head 15. In that case, mounting device 10 need only include one feeder section, one slide member 20, one X-axis moving device 30, and one Y-axis moving device 40, and one part camera 55, or one set of each.

In the embodiment, mounting device 10 that performs the mounting process as the production work has been described as an example; however, the configuration is not limited to this, and mounting device 10 need only be a working device provided with vacuum pump 71, that is, a working device that performs the production work using a vacuum pressure generated by vacuum pump 71. Additionally, management device 100 performs the pump state confirmation processing; however, the configuration is not limited to this, and mounting device 10 may perform the pump state confirmation processing.

### INDUSTRIAL APPLICABILITY

The present disclosure can be used for monitoring of a vacuum pump provided in a working device, and the like.

### REFERENCE SIGNS LIST

1: Mounting system, 10: Mounting device, 11: Housing, 12: Base, 13: Support stand, 15: Head, 15a: First head, 15b: Second head, 20: Slide member, 20a: First slide member, 20b: Second slide member, 30: X-axis moving device, 30a: First X-axis moving device, 30b: Second X-axis moving device, 40: Y-axis moving device, 40a: First Y-axis moving device, 40b: Second Y-axis moving device, 41: Y-axis linear guide, 42: Y-axis linear motor, 43: Y-axis stator, 44: Y-axis mover, 50a, 50b: Part camera, 55: Display operation panel, 70, 170: Pressure supply device, 71: Vacuum pump, 71a: First vacuum pump, 71b: Second vacuum pump, 71c: Third vacuum pump, 72: Pressure sensor, 73: First flow path, 74: Second flow path, 75, 79a, 79b: Connection flow path, 76: Third flow path, 77a, 77b, 177a, 177b: Component suction pickup flow path, 78a, 78b: Nozzle holding flow path, 90: Control device, 91, 101: CPU, 92, 102: ROM, 93, 103: HDD, 94, 104: RAM, 100: Management device, 103a: Pressure-related information database, 107: Input device, 108:

1. A monitoring system for monitoring pressures of multiple vacuum pumps provided in a working device, the monitoring system comprising:
a sensor configured to detect a pressure of an air flow path communicating with the multiple vacuum pumps;
a pressure acquisition section configured to execute acquisition processing of acquiring a detection value of the sensor as a pressure of an operating vacuum pump in a state in which one of the multiple vacuum pumps is operated and the remaining vacuum pumps are stopped, while sequentially switching the vacuum pump to be operated; and
a determination section configured to determine a state of each of the multiple vacuum pumps based on the pressure acquired in the acquisition processing.

2. The monitoring system according to claim 1,
wherein the pressure acquisition section executes the acquisition processing at a timing before a production work of the working device is started.

3. The monitoring system according to claim 1, further comprising:
an information acquisition section configured to acquire, as production information, information affected by a pressure change of the vacuum pump in a production work of the working device; and
a storage section configured to store the pressure acquired in the acquisition processing and the production information acquired in the production work before or after execution of the acquisition processing in association with each other,
wherein the determination section determines the state of each of the multiple vacuum pumps based on the pressure acquired in the acquisition processing and the production information associated with the pressure.

4. The monitoring system according to claim 3,
wherein the determination section determines that the vacuum pump is in a state of pressure abnormality when the pressure acquired in the acquisition processing is within a predetermined abnormal range, and determines whether the vacuum pump is in a state requiring maintenance based on the production information associated with the pressure when the pressure acquired in the acquisition processing is not within the abnormal range.

5. The monitoring system according to claim 1,
wherein the multiple vacuum pumps have predetermined timings of periodic maintenance, and
the determination section postpones the timing of periodic maintenance of the vacuum pump when the vacuum pump has reached the timing of periodic maintenance but the pressure acquired in the acquisition processing is within a predetermined normal range.

6. A monitoring system for monitoring a pressure of a vacuum pump provided in a working device, the monitoring system comprising:
a sensor configured to detect a pressure of an air flow path communicating with the vacuum pump;
a pressure acquisition section configured to execute, in a state in which the vacuum pump is operated, acquisition processing of acquiring a detection value of the sensor as a pressure of the operating vacuum pump;
an information acquisition section configured to acquire, as production information, information affected by a pressure change of the vacuum pump in a production work of the working device;
a storage section configured to store the pressure acquired in the acquisition processing and the production information acquired in the production work before or after execution of the acquisition processing in association with each other; and
a determination section configured to determine a state of the vacuum pump based on the pressure acquired in the acquisition processing and the production information associated with the pressure.

7. A monitoring method of monitoring pressures of multiple vacuum pumps provided in a working device, the monitoring method comprising:
(a) a step of executing acquisition processing of acquiring a detection value of a sensor configured to detect a pressure of an air flow path communicating with the multiple vacuum pumps as a pressure of an operating vacuum pump in a state in which one of the multiple vacuum pumps is operated and the remaining vacuum pumps are stopped, while sequentially switching the vacuum pump to be operated; and
(b) a step of determining a state of each of the multiple vacuum pumps based on the pressure acquired in the acquisition processing.
